(19) United States
(12) Patent Application Publication
(10) Pub. No.: US 2015/0333145 A1
(43) Pub. Date: Nov. 19, 2015

(54) HIGH DENSITY FINFET DEVICES WITH UNMERGED FINS

(71) Applicant: International Business Machines Corporation, Armonk, NY (US)

(72) Inventors: Michael P. Chudzik, Danbury, CT (US); Brian J. Greene, Wappingers Falls, NY (US); Edward P. Maciejewski, Wappingers Falls, NY (US); Kevin McStay, Hopewell Junction, NY (US); Shreesh Narasimha, Beacon, NY (US); Chengwen Pei, Danbury, CT (US); Werner A. Rausch, Stormville, NY (US)

(73) Assignee: International Business Machines Corporation, Armonk, NY (US)

(21) Appl. No.: 14/278,674

(22) Filed: May 15, 2014

(51) Int. Cl. H01L 29/66; H01L 29/78

(52) U.S. Cl. CPC H01L 29/6681; H01L 29/785; H01L 29/66545

(57) ABSTRACT

Embodiments of the present invention provide a finFET and method of fabrication to achieve advantages of both merged and unmerged fins. A first step of epitaxy is performed with either partial diamond or full diamond growth. This is followed by a second step of deposition of a semiconductor cap region on the finFET source/drain area using a directional deposition process, followed by an anneal to perform Solid Phase Epitaxy or poly recrystalization. As a result, the fins remain unmerged, but the epitaxial volume is increased to provide reduced contact resistance. Embodiments of the present invention allow a narrower fin pitch, which enables increased circuit density on an integrated circuit.

### FIELD OF THE INVENTION

The present invention relates generally to semiconductor fabrication, and more particularly, to field effect transistors and methods of fabrication.

### BACKGROUND OF THE INVENTION

Transistors, such as metal oxide semiconductor field-effect transistors (MOSFETs), are the core building block of the vast majority of semiconductor devices. Some semiconductor devices, such as high performance processor devices, can include millions of transistors. For such devices, decreasing transistors size, and thus increasing transistor density, has traditionally been a high priority in the semiconductor manufacturing industry. Fin type field effect transistor (FinFET) technology is becoming more prevalent as device size continues to shrink. It is therefore desirable to have improved finFET structures and methods of fabrication.

### SUMMARY OF THE INVENTION

Embodiments of the present invention provide growth of a thin undoped selective and conformal silicon layer on an epitaxial layer during the fabrication of finFET transistors. Embodiments utilize a deposition process to form silicon atop the epitaxial region. An anneal process is used to enable crystallization atop the epitaxial regions while not being formed on silicon dioxide isolation regions. The resultant shape is advantageous for balancing source/drain resistance and/or capacitance in the fabricated finFET devices and also allows for a reduced fin pitch, enabling increased circuit density.

In a first aspect, embodiments of the present invention provide a method of forming a semiconductor structure, comprising: forming a plurality of semiconductor fins on an insulator layer that is disposed on a semiconductor substrate; forming an epitaxial semiconductor region on each fin of the plurality of semiconductor fins; forming a semiconductor cap region on an upper portion of each of the epitaxial semiconductor regions, wherein the semiconductor cap region is disposed above, and separated from, the insulator layer; and performing an anneal on the semiconductor structure to convert the semiconductor cap region to a crystalline semiconductor cap region.

In a second aspect, embodiments of the present invention provide a method of forming a semiconductor structure, comprising: forming a plurality of semiconductor fins on an insulator layer that is disposed on a semiconductor substrate; forming a dummy gate over the plurality of semiconductor fins; forming a epitaxial semiconductor region on each fin of the plurality of semiconductor fins; forming a semiconductor cap region on an upper portion of each of the epitaxial semiconductor regions, wherein the semiconductor cap region is disposed above, and separated from, the insulator layer; performing an anneal on the semiconductor structure to convert the semiconductor cap region to a crystalline semiconductor cap region; removing the dummy gate; and forming a metal gate in place of the dummy gate.

In a third aspect, embodiments of the present invention provide a semiconductor structure comprising: a semiconductor substrate; an insulator layer disposed on the semiconductor substrate; a plurality of fins disposed on the insulator layer; and a crystalline semiconductor region disposed on each fin of the plurality of fins, wherein each crystalline semiconductor region is unmerged, and comprises a partial diamond portion and a semiconductor cap portion.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG). Furthermore, for clarity, some reference numbers may be omitted in certain drawings.

FIG. 1 is a semiconductor structure at a starting point for embodiments of the present invention.

FIG. 2 is a semiconductor structure after a subsequent process step of forming a dummy gate.

FIG. 3 is a top-down view of the semiconductor structure of FIG. 2.

FIG. 4A is a semiconductor structure after a subsequent process step of forming a partial diamond semiconductor region on each fin.

FIG. 4B and FIG. 4C show details of a partial diamond semiconductor region.

FIG. 5 is a semiconductor structure after a subsequent process step of forming a semiconductor cap region on each fin.

FIG. 6 is a semiconductor structure after a subsequent process step of converting each semiconductor cap region to a crystalline semiconductor cap region.

FIG. 7A is a semiconductor structure at a starting point for embodiments of the present invention utilizing a fin cut.

FIG. 7B is a semiconductor structure after subsequent process steps gate replacement, in accordance with embodiments of the present invention.

FIG. 8 is a semiconductor structure after a subsequent process step of silicide formation, in accordance with embodiments of the present invention.

FIG. 9 is a semiconductor structure at a starting point for alternative embodiments of the present invention.

FIG. 10 is a semiconductor structure after a subsequent process step of forming a full diamond semiconductor region on each fin.

FIG. 11 is a semiconductor structure after a subsequent process step of forming a semiconductor cap region on each fin.

FIG. 12 is a semiconductor structure after a subsequent process step of converting each semiconductor cap region to a crystalline semiconductor cap region.

FIG. 13 is a semiconductor structure after a subsequent process step of silicide formation, in accordance with embodiments of the present invention.

FIG. 14 is a flowchart indicating process steps for embodiments of the present invention.

### DETAILED DESCRIPTION

Exemplary embodiments will now be described more fully herein with reference to the accompanying drawings, in which one or more approaches are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying,” “on,” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

In the fabrication of finFETs, defective merged epitaxial regions are a major source of defects. Therefore unmerged fins (fins with separated epitaxial regions) are advantageous in terms of reducing these defects. However, unmerged fins have a potential performance penalty due to high external resistance. Embodiments of the present invention provide an improved finFET and method of fabrication to mitigate these issues and achieve advantages of both merged and unmerged fins. A first step of epitaxy is performed with either partial diamond or full diamond growth. This is followed by a second step of deposition of a semiconductor cap region on the finFET source/drain area using a directional deposition process, followed by an anneal to perform Solid Phase Epitaxy or poly recrystalization. As a result, the fins remain unmerged, but the epitaxial volume is increased to provide reduced contact resistance. Embodiments of the present invention allow a narrower fin pitch, which enables increased circuit density on an integrated circuit.

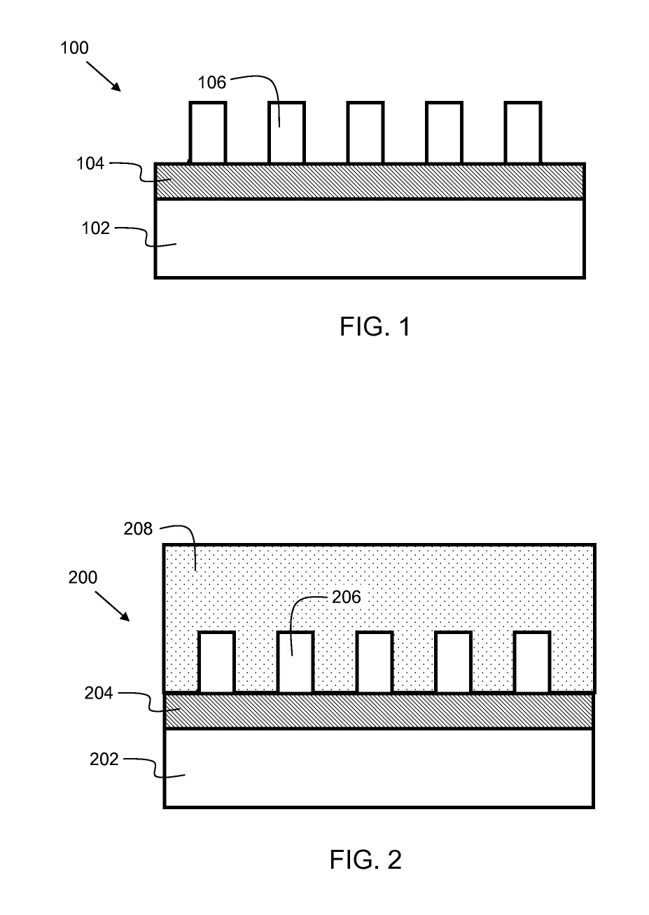

FIG. 1 is a semiconductor structure 100 at a starting point for embodiments of the present invention. Semiconductor structure 100 comprises semiconductor substrate 102. In embodiments, semiconductor substrate 102 comprises a silicon wafer. An insulator layer 104 is disposed on the semiconductor substrate 102. In embodiments, the insulator layer 104 may be comprised of silicon oxide, and may be referred to as a buried oxide (BOX) layer. A plurality of semiconductor fins 106 are formed on the insulator layer 104. In embodiments, the semiconductor fins 106 may be comprised of silicon, silicon germanium (SiGe), or other suitable material. In embodiments, the semiconductor fins 106 may be formed by a sidewall image transfer (SIT) process or other suitable process. Note that while the illustrated embodiments of this disclosure, including semiconductor structure 100, show a semiconductor-on-insulator (SOI) type of structure, embodiments of the present invention may also utilize a bulk semiconductor structure, where no insulator layer 104 is present. In such embodiments, the fins 106 are formed directly on the semiconductor substrate 102, and a doped region (e.g. punchthrough stopper) may be utilized to provide isolation of the fins.

FIG. 2 is a semiconductor structure 200 after a subsequent process step of forming a dummy gate 208. As mentioned previously, often, similar elements may be referred to by similar numbers in various figures (FIGs) of the drawing, in which case typically the last two significant digits may be the same, the most significant digit being the number of the drawing figure (FIG). For example, semiconductor substrate 202 of FIG. 2 is similar to semiconductor substrate 102 of FIG. 1. In embodiments, the dummy gate is comprised of polysilicon.

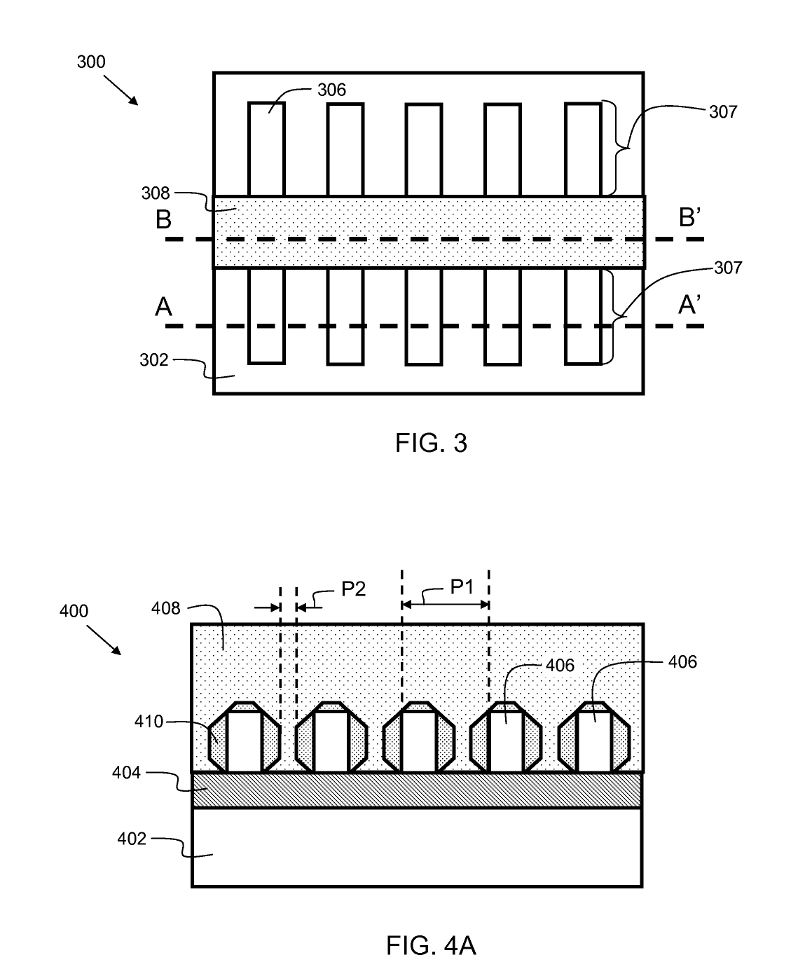

FIG. 3 is a top-down view 300 of a semiconductor structure similar to that of FIG. 2.

As can be seen in this view, a plurality of fins 306 are disposed on semiconductor substrate 302. In the case of a SOI structure, an insulator layer (see 204 of FIG. 2) is disposed between fins 306 and semiconductor substrate 302. The dummy gate 308 is disposed perpendicular to, and disposed over the fins 306. Source/drain regions of fins 307 are outside of the gate 308. A spacer region (not shown) may be formed adjacent to gate 308.

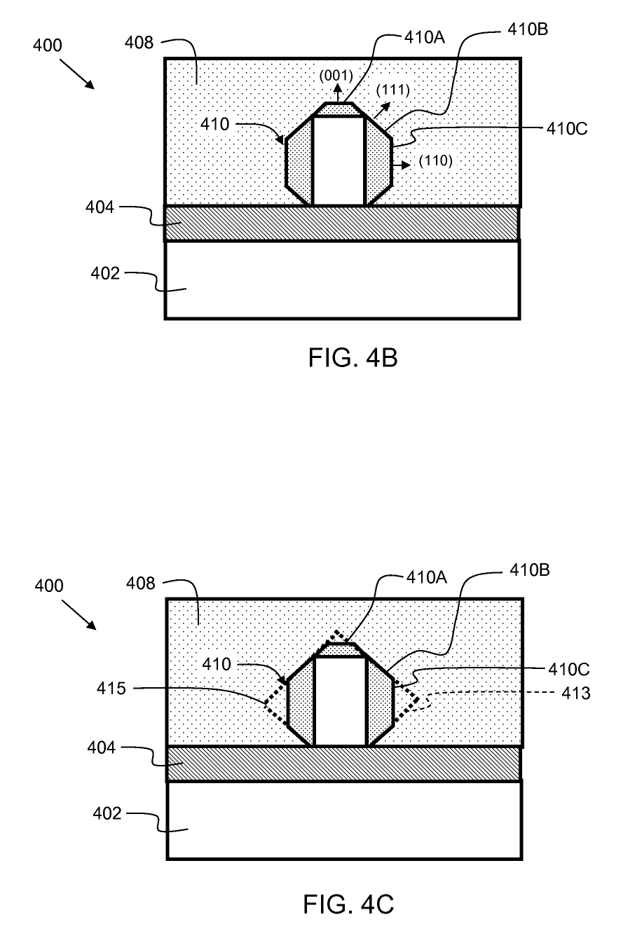

FIG. 4A is a semiconductor structure 400 after a subsequent process step of forming a partial diamond semiconductor region 410 on each fin 406. The fins 406 are shown as viewed along line A-A′ of FIG. 3, while the gate structure 408 is as viewed along line B-B′ of FIG. 3. The fins 406 have a pitch P1. In embodiments, P1 may range from about 30 nanometers to about 80 nanometers. The partial diamond semiconductor regions are separated from each other by a distance P2. In embodiments, P2 may range from about 5 nanometers to about 20 nanometers.

FIG. 4B and FIG. 4C show details of a partial diamond semiconductor region 410 of semiconductor structure 400. The partial diamond semiconductor region comprises top surface 410A, corner surface 410B, and side surface 410C. The partial diamond semiconductor region 410 has a faceted shape because of the crystalline structure of the fins on which it is grown. In embodiments, the top surface 410A has a (001) crystalline structure, the corner surface 410B has a (111) crystalline structure, and the side surface 410C has a (110) crystalline structure. The growth rate for each crystalline structure is different, and the faceted shape results. If the growth continues, the semiconductor region becomes a full diamond region as indicated by reference 413 of FIG. 4C, which includes outer vertex 415. However, the growth is stopped prior to reaching the full diamond shape, and hence, semiconductor region 410 is a partial diamond which does not include outer vertex 415, and thus, the fins 406 (FIG. 4A) do not touch each other, and remain unmerged. In a subsequent process step, a thin, undoped, conformal layer may be deposited on each fin.

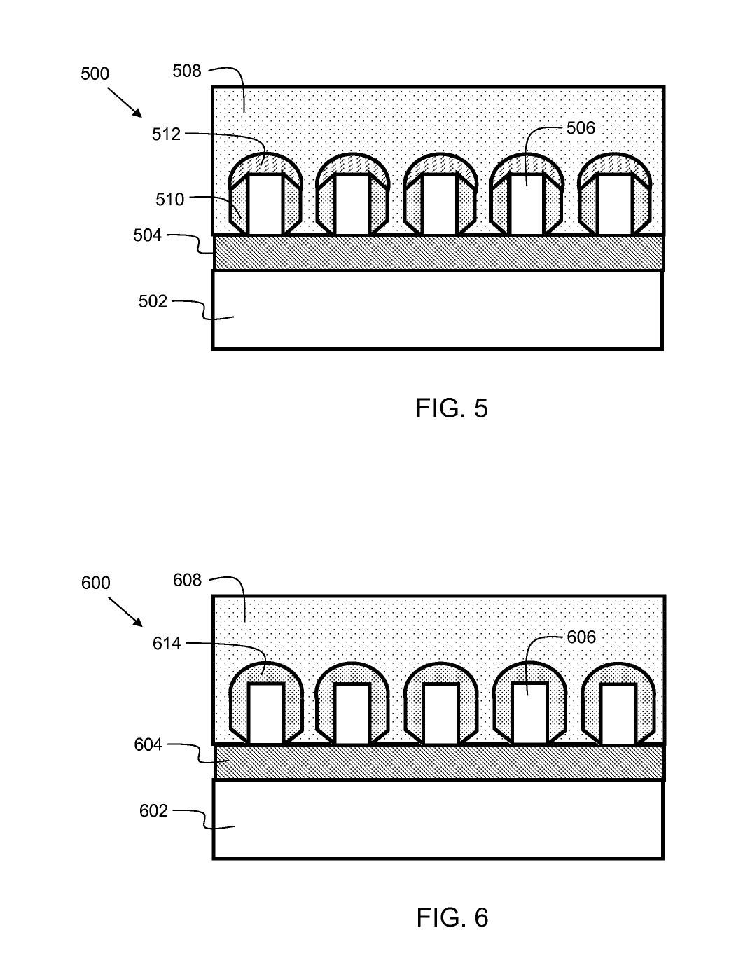

FIG. 5 is a semiconductor structure 500 after a subsequent process step of forming a semiconductor cap region 512 on an upper portion of each fin 506, and being disposed above, and separated from, insulator layer 504. In embodiments, the semiconductor cap region is a thin, undoped, conformal layer that is deposited using a physical vapor deposition (PVD) process. In embodiments, the semiconductor cap is comprised of a semiconductor material that may include, but is not limited to, amorphous silicon, polycrystalline silicon, amorphous silicon germanium, and polycrystalline silicon germanium. The deposition process may be selective such that the semiconductor cap material is not substantially deposited on the insulator layer 504.

FIG. 6 is a semiconductor structure 600 after a subsequent process step of converting each semiconductor cap region to a crystalline semiconductor region 614 which is unmerged, and comprises the partial diamond portion (510 of FIG. 5) and the semiconductor cap portion 512. The conversion may be performed using an anneal. In embodiments, the anneal is a thermal anneal that is performed at a process temperature ranging from about 500 degrees Celsius to about 650 degrees Celsius to enable a re-crystallization process. In other embodiments, the anneal is a Solid Phase Epitaxy (SPE) process that is performed at a process temperature ranging from about 500 degrees Celsius to about 600 degrees Celsius. The crystalline semiconductor region 614 provides additional epitaxial volume, and yet the fins remain unmerged. The resultant shape of the crystalline semiconductor region 614 is advantageous for balancing source/drain resistance and capacitance in the completed integrated circuits (ICs). Hence the structure provides advantages of merged epitaxial fins (increased epitaxial volume for reduced intrinsic source/drain resistance and increased contact surface area) and also provides advantages of unmerged fins (improved yield/reduced defects by having fins remain in an unmerged state).

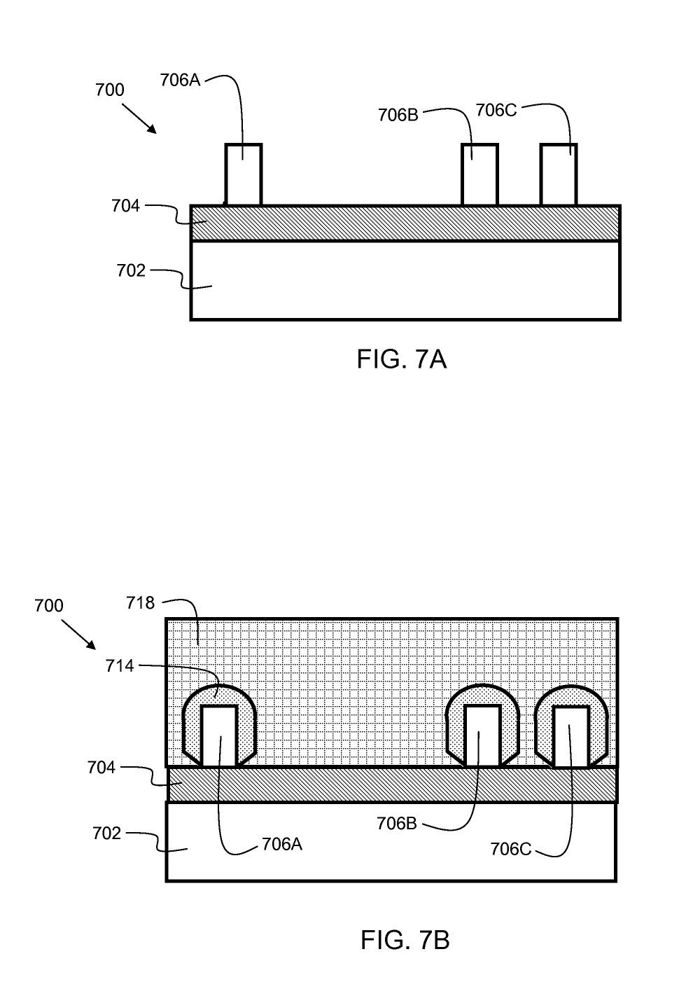

FIG. 7A shows a semiconductor 700 structure similar to that shown in FIG. 1, but with the added step of performing a fin cut to remove some of the fins. In the cases where it is desired to remove some of the fins, the fin cut step may be performed prior to deposition of the semiconductor cap region. FIG. 7B is a semiconductor structure 700 after subsequent process steps of fin cut and gate replacement, in accordance with embodiments of the present invention. The dummy gate is removed and a high-K dielectric layer (not shown) and metal gate 718 is deposited in its place. This may be accomplished using a replacement metal gate (RMG) process. In embodiments, one or more fins may be cut as shown in FIG. 7A. As shown in this example, fin 706A is alone, and may be a part of a single-fin finFET. Fins 706B and 706C may be part of a multiple-fin finFET with unmerged fins. Note that while the illustrated embodiments show a replacement metal gate (gate-last) process flow, embodiments of the present invention may also be utilized with a gate-first process flow. The structure 700 is annealed to enable crystallization atop the diamond shaped epitaxial regions and not on the insulator region 704. Crystalline semiconductor region 714 provides a shape that is advantageous for balancing source/drain resistance and capacitance in the final product.

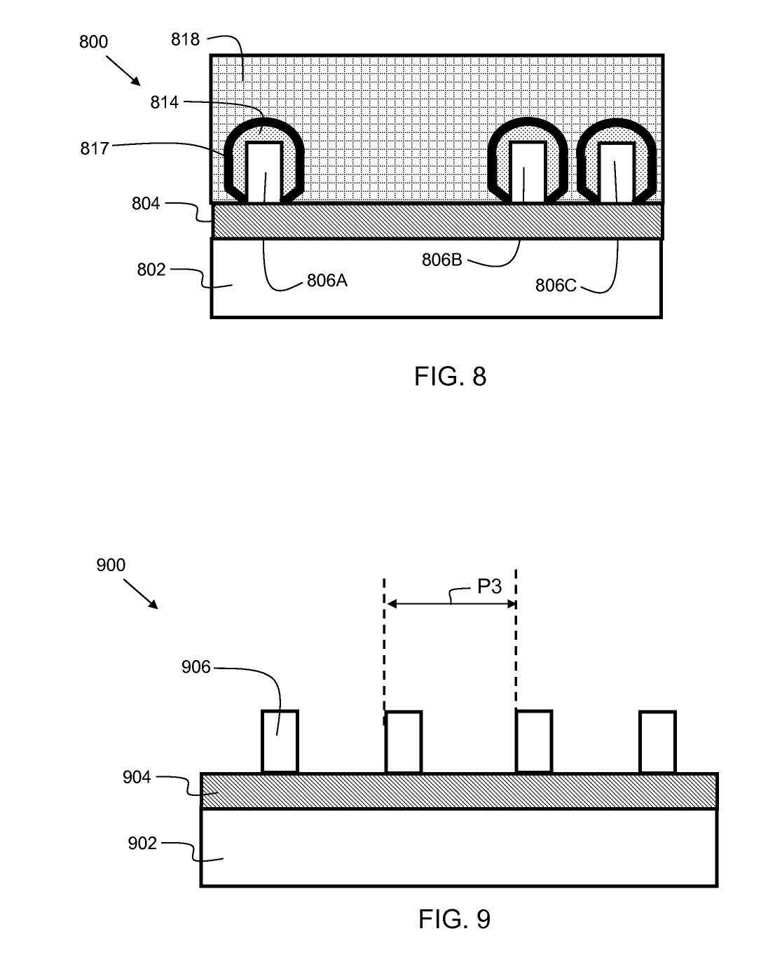

FIG. 8 is a semiconductor structure 800 after a subsequent optional process step of silicide formation, in accordance with embodiments of the present invention. Silicide regions 817 may be formed as a wrap-around silicidation around the crystalline semiconductor cap region 814, which serves to lower the contact resistance, thereby improving semiconductor device performance. Hence, the silicide region 817 may be applied to both the semiconductor cap region and the exposed sides of the partial diamond semiconductor region to further reduce contact resistance. In embodiments, the silicide regions 817 may include, but are not limited to, nickel silicide and/or cobalt silicide. In embodiments, the silicide may be formed by depositing a metal, such as nickel, titanium, or cobalt, using an atomic layer deposition (ALD) process. An anneal at a process temperature ranging from about 350 degrees Celsius to about 400 degrees Celsius may then be performed to create the silicide regions 817, followed by removal of any excess metal.

FIG. 9 is a semiconductor structure 900 at a starting point for alternative embodiments of the present invention. Semiconductor structure 900 comprises semiconductor substrate 902. In embodiments, semiconductor substrate 902 comprises a silicon wafer. An insulator layer 904 is disposed on the semiconductor substrate 902. In embodiments, the insulator layer 904 may be comprised of silicon oxide, and may be referred to as a buried oxide (BOX) layer. A plurality of semiconductor fins 906 are formed on the insulator layer 104. In embodiments, the semiconductor fins 906 may be comprised of silicon, silicon germanium (SiGe), or other suitable material. The fins 906 have a pitch P3. In embodiments, P3 ranges from about 80 nanometers to about 100 nanometers. In this embodiment, the pitch P3 is sufficiently wide to facilitate a full diamond semiconductor region while still remaining unmerged.

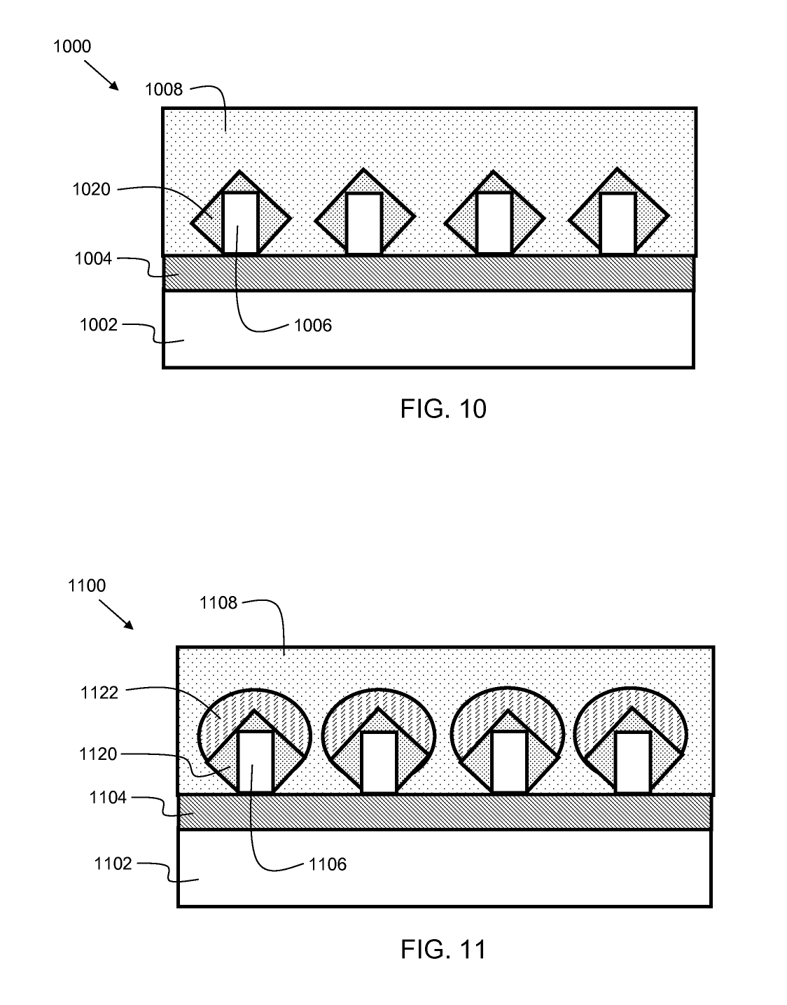

FIG. 10 is a semiconductor structure 1000 after a subsequent process step of depositing a dummy gate 1008, and then forming a full diamond semiconductor region 1020 on each fin. The fins 1006 are shown as viewed along line A-A′ of FIG. 3, while the gate structure 1008 is as viewed along line B-B′ of FIG. 3. The diamond shaped epitaxial layer is used for subsequent forming of a conformal crystalline silicon layer in subsequent processing.

FIG. 11 is a semiconductor structure 1100 after a subsequent process step of forming a semiconductor cap region 1122 on each fin. In embodiments, the semiconductor cap region is deposited using a physical vapor deposition (PVD) process. In embodiments, the semiconductor cap material may include, but is not limited to, amorphous silicon, polycrystalline silicon, amorphous silicon germanium, and polycrystalline silicon germanium.

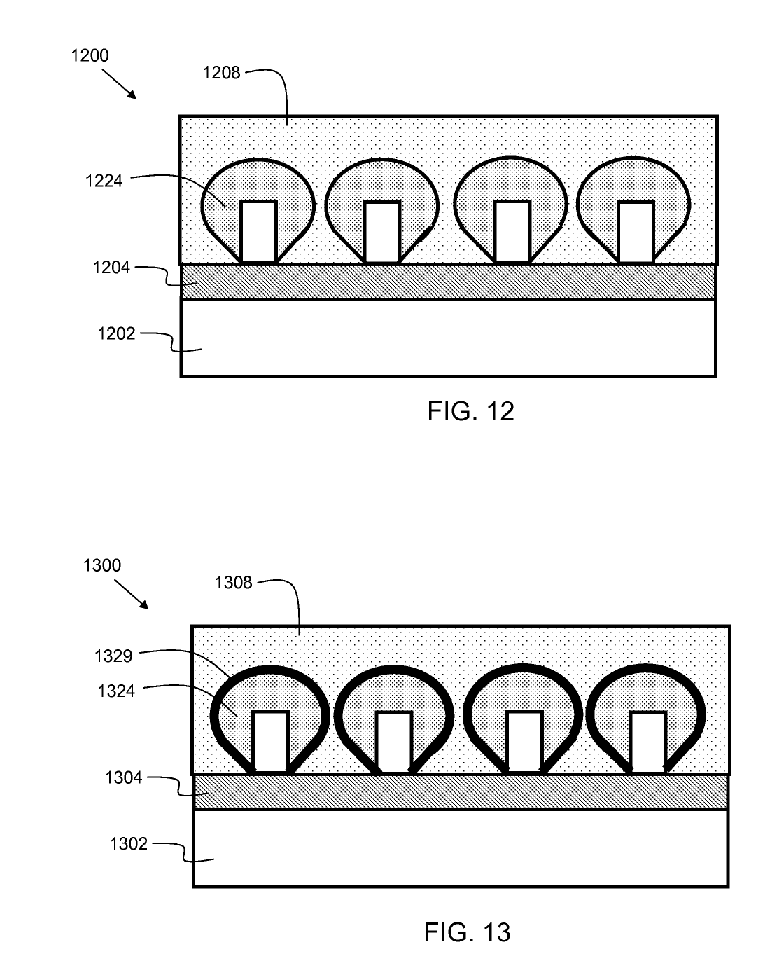

FIG. 12 is a semiconductor structure 1200 after a subsequent process step of converting each semiconductor cap region to a crystalline semiconductor cap region 1224. The conversion may be performed using an anneal. The structure 1200 is annealed to enable crystallization atop the diamond shaped epitaxial regions and not on the insulator region 1204. In embodiments, the anneal is a thermal anneal that is performed at a process temperature ranging from about 500 degrees Celsius to about 650 degrees Celsius. In other embodiments, the anneal is a Solid Phase Epitaxy (SPE) process that is performed at a process temperature ranging from about 500 degrees Celsius to about 600 degrees Celsius. The crystalline semiconductor cap region 1224 provides additional epitaxial volume, and yet the fins remain unmerged. Hence the structure provides advantages of merged epitaxial fins (increased epitaxial volume for reduced contact resistance) and also provides advantages of unmerged fins (improved yield/reduced defects by having fins remain in an unmerged state).

FIG. 13 is a semiconductor structure 1300 after formation of a silicide layer 1329 on the crystalline semiconductor cap region 1324, similar to as described and shown in FIG. 8. The silicide may lower the contact resistance, thereby improving semiconductor device performance. In embodiments, the silicide layer 1329 may include, but are not limited to, nickel silicide, titanium, and/or cobalt silicide.

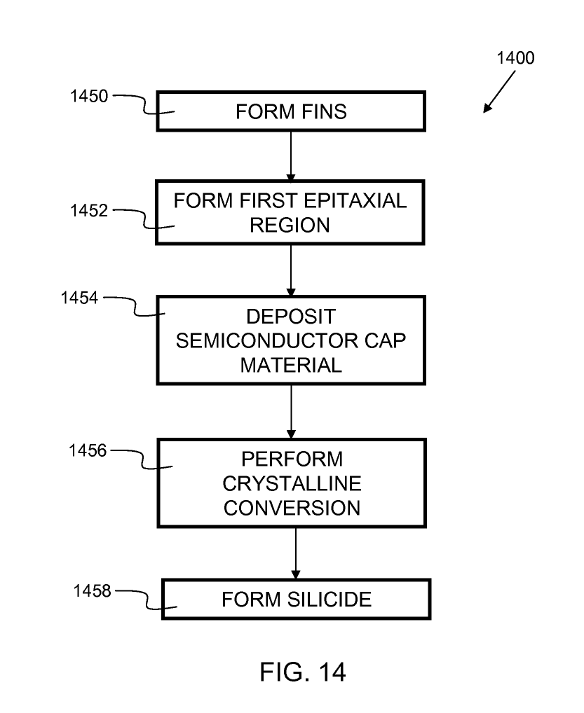

FIG. 14 is a flowchart 1400 indicating process steps for embodiments of the present invention. In process step 1450, fins are formed (see 106 of FIG. 1). In process step 1452, an epitaxial region is formed (see 410 of FIG. 4). In process step 1454, a semiconductor cap material is deposited (see 512 of FIG. 5). In process step 1456, a crystalline conversion is performed, resulting in crystalline semiconductor region (see 614 of FIG. 6). Optionally, in process step 1458, silicide regions are formed on the crystalline semiconductor cap region (see 817 of FIG. 8).

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A method of forming a semiconductor structure, comprising:
forming a plurality of semiconductor fins on an insulator layer that is disposed on a semiconductor substrate;
forming an epitaxial semiconductor region on each fin of the plurality of semiconductor fins;
forming a semiconductor cap region on an upper portion of each of the epitaxial semiconductor regions, wherein the semiconductor cap region is disposed above, and separated from, the insulator layer; and
performing an anneal on the semiconductor structure to convert the semiconductor cap region to a crystalline semiconductor cap region.

2. The method of claim 1, wherein forming an epitaxial semiconductor region comprises forming a full diamond region.

3. The method of claim 1, wherein forming an epitaxial semiconductor region comprises forming a partial diamond region.

4. The method of claim 1, wherein forming a semiconductor cap region comprises depositing a semiconductor material using a physical vapor deposition process.

5. The method of claim 4, wherein depositing a semiconductor material comprises depositing amorphous silicon.

6. The method of claim 4, wherein depositing a semiconductor material comprises depositing polysilicon.

7. The method of claim 4, wherein depositing a semiconductor material comprises depositing silicon germanium.

8. The method of claim 6, wherein performing an anneal comprises performing an anneal at a process temperature ranging from about 500 degrees Celsius to about 650 degrees Celsius.

9. The method of claim 5, wherein performing an anneal comprises performing an anneal at a process temperature ranging from about 500 degrees Celsius to about 600 degrees Celsius.

10. The method of claim 1, further comprising forming a silicide layer over each crystalline semiconductor cap region.

11. The method of claim 10, wherein forming a silicide layer comprises forming a nickel silicide layer.

12. A method of forming a semiconductor structure, comprising:
forming a plurality of semiconductor fins on an insulator layer that is disposed on a semiconductor substrate;
forming a dummy gate over the plurality of semiconductor fins;
forming a epitaxial semiconductor region on each fin of the plurality of semiconductor fins;
forming a semiconductor cap region on an upper portion of each of the epitaxial semiconductor regions, wherein the semiconductor cap region is disposed above, and separated from, the insulator layer;
performing an anneal on the semiconductor structure to convert the semiconductor cap region to a crystalline semiconductor cap region;
removing the dummy gate; and
forming a metal gate in place of the dummy gate.

13. The method of claim 12, wherein depositing a semiconductor material comprises depositing amorphous silicon.

14. The method of claim 12, wherein depositing a semiconductor material comprises depositing polysilicon.

15. The method of claim 12, wherein depositing a semiconductor material comprises depositing silicon germanium.

16. A semiconductor structure comprising:
a semiconductor substrate;
an insulator layer disposed on the semiconductor substrate;
a plurality of fins disposed on the insulator layer; and
a crystalline semiconductor region disposed on each fin of the plurality of fins, wherein each crystalline semiconductor region is unmerged, and comprises a partial diamond portion and a semiconductor cap portion.

17. The semiconductor structure of claim 16, further comprising a silicide layer disposed on the crystalline semiconductor region of each fin of the plurality of fins.

18. The semiconductor structure of claim 17, wherein the silicide layer comprises nickel.

19. The semiconductor structure of claim 16, wherein the crystalline semiconductor region is comprised of silicon germanium.

20. The semiconductor structure of claim 16, wherein the crystalline semiconductor region is comprised of silicon.
